(19) United States
(12) Patent Application Publication
(10) Pub. No.: US 2026/0323936 A1
(43) Pub. Date: Oct. 15, 2026

(54) COMPLEMENTARY FIELD-EFFECT TRANSISTOR CIRCUIT AND ASSOCIATED ONE-TIME PROGRAMMABLE MEMORY CELL

(71) Applicant: eMemory Technology Inc., Hsin-Chu (TW)

(72) Inventors: Lun-Chun CHEN, Hsinchu county (TW); Ping-Lung HO, Hsinchu County (TW)

(73) Assignee: eMemory Technology Inc., Hsin-Chu (TW)

(21) Appl. No.: 19/641,743

(22) Filed: Apr. 8, 2026

Related U.S. Application Data
(60) Provisional application No. 63/788,176, filed on Apr. 14, 2025.

(51) Int. Cl. H10B 20/25

(52) U.S. Cl. CPC H10B 20/25

(57) ABSTRACT

A complementary field-effect transistor circuit includes a first complementary field-effect transistor and a second complementary field-effect transistor. The first complementary field-effect transistor includes a first element and a second element. The second complementary field-effect transistor includes a third element and a fourth element. In the first one-time programmable memory cell, a first drain/source terminal of the second element is electrically connected with a bit line, a gate terminal of the second element is electrically connected with a word line, a first drain/source terminal of the fourth element is electrically coupled to a second drain/source terminal of the second element, and a gate terminal of the fourth element is electrically connected with an antifuse control line.

This application claims the benefit of U.S. provisional application Ser. No. 63/788,176, filed Apr. 14, 2025, the subject matters of which is incorporated herein by reference.

### FIELD OF THE INVENTION

The present invention relates to a non-volatile memory, and more particularly to a complementary field-effect transistor circuit and an associated one-time programmable memory cell.

### BACKGROUND OF THE INVENTION

As known, non-volatile memories can be classified into multi-time programmable memory cells (also referred to as MTP memory cells), one-time programmable memory cells (also referred to as OTP memory cells) and mask read only memory cells (also referred to as Mask ROM cells).

Generally, the MTP memory cell can be programmed many times, and the stored data of the MTP memory cell can be modified many times. On the contrary, the OTP memory cell can be programmed once. After the OTP memory cell is programmed, the stored data cannot be modified. Moreover, after the Mask ROM leaves the factory, all stored data have been recorded in the memory cells thereof. The user is only able to read the stored data from the Mask ROM, but is unable to program the Mask ROM.

For example, before an antifuse-type OTP memory cell is programmed, the memory cell is in a high-resistance storage state. After the antifuse-type OTP memory cell is programmed, the memory cell is in a low-resistance storage state. Furthermore, after the antifuse-type OTP memory cell is programmed, the stored data cannot be modified. Of course, a plurality of antifuse-type OTP memory cells can be collaboratively formed as an OTP memory.

### SUMMARY OF THE INVENTION

An embodiment of the present invention provides a complementary field-effect transistor circuit. The complementary field-effect transistor circuit includes a first complementary field-effect transistor and a second complementary field-effect transistor. The first complementary field-effect transistor includes a first element, a second element and an isolation structure. The second complementary field-effect transistor includes a third element, a fourth element and the isolation structure. The second element and the fourth element are portions of a first one-time programmable memory cell. The first element and the third element are portions of a second one-time programmable memory cell. The isolation structure is extended along an X-Y plane. The first one-time programmable memory cell is located beside a first side of the isolation structure in a Z direction. The second one-time programmable memory cell is located beside a second side of the isolation structure in a Z direction. In the first one-time programmable memory cell, a first drain/source terminal of the second element is electrically connected with a first bit line, a gate terminal of the second element is electrically connected with a first word line, a first drain/source terminal of the fourth element is electrically coupled to a second drain/source terminal of the second element, and a gate terminal of the fourth element is electrically connected with a first antifuse control line.

Another embodiment of the present invention provides a complementary field-effect transistor circuit. The complementary field-effect transistor circuit includes a first complementary field-effect transistor. The first complementary field-effect transistor includes a first element, a second element and an isolation structure. The first element and the second element are portions of a one-time programmable memory cell. The isolation structure is extended along an X-Y plane. The first element is located beside a first side of the isolation structure in a Z direction. The second element is located beside a second side of the isolation structure in a Z direction. In the complementary field-effect transistor, a first drain/source terminal of the second element is electrically connected with a first bit line, a gate terminal of the second element is electrically connected with a first word line, a first drain/source terminal of the first element is electrically connected with a second drain/source terminal of the second element, and a gate terminal of the first element is electrically connected with an antifuse control line.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A is a schematic perspective view illustrating a P-type element in a complementary field-effect transistor according to an embodiment of the present invention;

FIG. 1B is a schematic perspective view illustrating the P-type element in the complementary field-effect transistor and an isolation structure;

FIG. 1C is a schematic perspective view illustrating the structure of the complementary field-effect transistor;

FIG. 1D is a schematic cross-sectional view illustrating the complementary field-effect transistor shown in FIG. 1C and taken along the line ab;

FIG. 1E is a schematic perspective view illustrating the structure of another complementary field-effect transistor;

FIG. 1F is a schematic perspective view illustrating the structure of a further complementary field-effect transistor;

FIG. 2A schematically illustrates a CFET circuit according to a first embodiment of the present invention;

FIGS. 2B and 2C illustrate associated bias voltages and operations of performing a program action on the CFET circuit according to the first embodiment of the present invention;

FIGS. 2D and 2E illustrate associated bias voltages and operations of performing a read action on the CFET circuit according to the first embodiment of the present invention;

FIG. 3 schematically illustrates a CFET circuit according to a second embodiment of the present invention;

FIG. 4A schematically illustrates a CFET circuit according to a third embodiment of the present invention;

FIGS. 4B and 4C illustrate associated bias voltages and operations of performing a program action on the CFET circuit according to the third embodiment of the present invention;

FIGS. 4D and 4E illustrate associated bias voltages and operations of performing a read action on the CFET circuit according to the third embodiment of the present invention;

FIG. 5 schematically illustrates a CFET circuit according to a fourth embodiment of the present invention;

FIG. 6 schematically illustrates a CFET circuit according to a fifth embodiment of the present invention; and

FIG. 7 schematically illustrates a CFET circuit according to a sixth embodiment of the present invention.

### DETAILED DESCRIPTION OF PREFERRED EMBODIMENTS

The present invention provides a one-time programmable memory cell for a non-volatile memory.

As used herein, the term “ruptured” may be referred to as “quantum-tunneling” technique. In detail, after energy accumulated on the gate terminal of a complementary field-effect transistor reaches a certain level, quantum-tunneling may occur on the complementary field-effect transistor. The energy accumulated on the gate terminals of the complementary field-effect transistor will be released via a gate leakage path of which undergoing quantum-tunneling. Thus, the complementary field-effect transistor would generate a quantum-tunneling current higher than a predetermined threshold value. The mechanism of quantum-tunneling mentioned above may be similar to a gate oxide breakdown, but is not limited to a hard/destructive breakdown. For example, the quantum-tunneling may be a soft breakdown that leverages trap-assisted tunneling, but the present invention is not limited thereto. For better comprehension, the complementary field-effect transistor which generates a quantum-tunneling current higher than the predetermined threshold value may be referred to as being “ruptured”, and the complementary field-effect transistor which generates a quantum-tunneling current lower than the predetermined threshold value (or does not undergo the quantum-tunneling) may be referred to as being “unruptured”.

A complementary field-effect transistor (CFET) is new type of vertical transistor. The CFET includes an N-type element and a P-type element. The CFET is formed over a semiconductor substrate. The N-type element and the P-type element are stacked together to reduce the layout area of the IC circuit. For example, the P-type element is located over the semiconductor substrate, and the N-type element is located over the P-type element. For illustration, the semiconductor substrate is not shown in the following drawings.

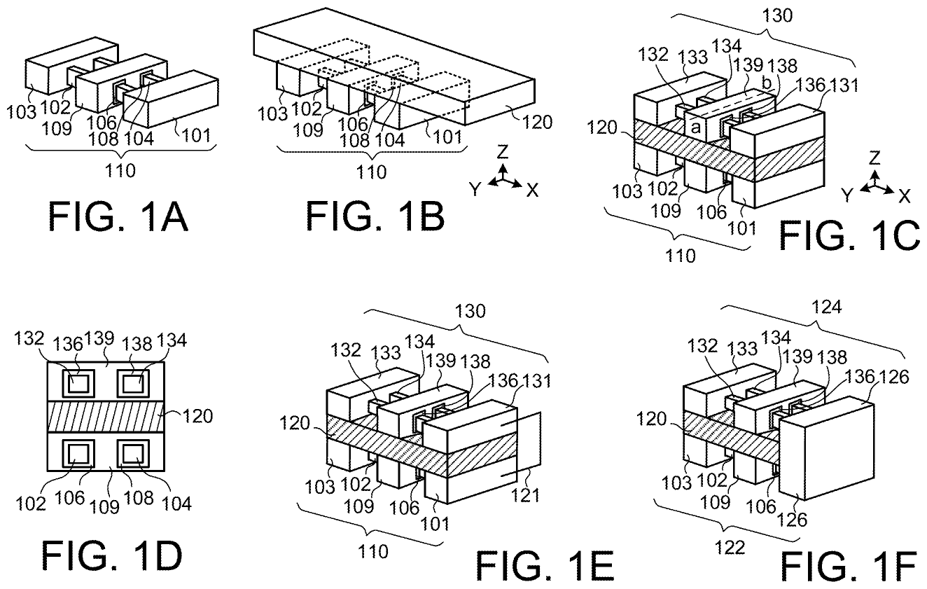

FIG. 1A is a schematic perspective view illustrating a P-type element in a complementary field-effect transistor according to an embodiment of the present invention. FIG. 1B is a schematic perspective view illustrating the P-type element in the complementary field-effect transistor and an isolation structure. FIG. 1C is a schematic perspective view illustrating the structure of the complementary field-effect transistor. FIG. 1D is a schematic cross-sectional view illustrating the complementary field-effect transistor shown in FIG. 1C and taken along the line ab.

As shown in FIG. 1A, the P-type element includes two drain/source structures 101 and 103, a gate structure, and two nanosheets 102 and 104. The gate structure surrounds the center regions of nanosheets 102 and 104. The center region of nanosheets 102 and 104 can be regarded as the channel region of the P-type element 110.

The source/drain structure 101 is electrically connected with the first side regions of the nanosheets 102 and 104. The source/drain structure 103 is electrically connected with the second side regions of the nanosheets 102 and 104. In other words, the first terminal of the nanosheets 102 and 104 are electrically connected with the source/drain structure 101, and the second terminals of the nanosheets 102 and 104 are electrically connected with the source/drain structure 103.

As shown in FIG. 1A and FIG. 1D, the gate structure of the P-type element 110 includes a gate layer 109 and two gate dielectric layers 106 and 108. The gate dielectric layers 106 and 108 surround the center regions of the nanosheets 102 and 104, respectively. Furthermore, the gate layer 109 surrounds the gate dielectric layers 106 and 108, and the gate layer 109 is not electrically contacted with the nanosheets 102 and 104.

As mentioned above, the gate layer 109 can be used as the gate terminal of the P-type element 110, and the two drain/source structures 101 and 103 can be used as the two drain/source terminals of the P-type element 110.

The nanosheets 102 and 104 in P-type element 110 have various dopant types. For example, the first side region and the second side region of each of the nanosheets 102 and 104 are P-type doped regions, and the center region of each of the nanosheets 102 and 104 is an undoped region. Alternatively, the center region of each of the nanosheets 102 and 104 is a P-type doped region, and the first side region and the second side region of each of the nanosheets 102 and 104 are undoped regions. Alternatively, all regions of the nanosheets 102 and 104 are P-type doped regions.

As shown in FIG. 1B, an isolation structure 120 is located over the P-type element 110. The isolation structure 120 can be used to electrically isolated from the P-type element 110 and the N-type element of the complementary field-effect transistor. Of course, if a plurality of complementary field-effect transistors are simultaneously fabricated on a semiconductor substrate, the P-type elements and the N-type elements of all complementary field-effect transistors can be electrically isolated through the isolation structure 120. In some embodiments, the isolation structure 120 is used to isolate the P-type element 110 from the N-type element in the Z direction. That is, the isolation structure 120 is not contacted with the semiconductor substrate, and the isolation structure 120 is extended above the semiconductor substrate along the X-Y plane. Consequently, the P-type element 110 and the N-type element are respectively located beside both sides of the isolation structure 120 in the Z direction.

As shown in FIG. 1C, the complementary field-effect transistor includes the P-type element 110, the isolation structure 120 and an N-type element 130. The N-type element 130 is located over the isolation structure 120. The N-type element 130 includes two drain/source structures 131 and 133, a gate structure, and two nanosheets 132 and 134. The gate structure surrounds the center regions of the nanosheets 132 and 134. The center regions of the nanosheets 132 and 134 can be regarded as the channel region of the N-type element 130.

The source/drain structure 131 is electrically connected with the first side regions of the nanosheets 132 and 134. The source/drain structure 133 is electrically connected with the second side regions of the nanosheets 132 and 134. In other words, the first terminals of the nanosheets 132 and 134 are electrically connected with the source/drain structure 131, and the second terminals of the nanosheets 132 and 134 are electrically connected with the source/drain structure 133.

As shown in FIG. 1C and FIG. 1D, the gate structure of the N-type element 130 includes a gate layer 139 and two gate dielectric layers 136 and 138. The gate dielectric layers 136 and 138 surround the center regions of the nanosheets 132 and 134, respectively. Furthermore, the gate layer 139 surrounds the gate dielectric layers 136 and 138, and the gate layer 139 is not electrically contacted with the nanosheets 132 and 134.

As mentioned above, the gate layer 139 can be used as the gate terminal of the N-type element 130, and the two drain/source structures 131 and 133 can be respectively used as the two drain/source terminals of the N-type element 130.

Similarly, nanosheets 132 and 134 in N-type element 130 have various dopant types. For example, the first side region and the second side region of each of the nanosheets 132 and 134 are N-type doped regions, and the center regions of the nanosheets 132 and 134 are undoped regions. Alternatively, the center regions of the nanosheets 132 and 134 are N-type doped regions, and the first side region and the second side region of each of the nanosheets 132 and 134 are undoped regions. Alternatively, all regions of the nanosheets 132 and 134 are N-type doped regions.

As shown in FIG. 1C, the P-type element 110 and the N-type element 130 are isolated from each other through the isolation structure 120. Consequently, the P-type element 110 and the N-type element 130 are not contacted with each other. In other words, the two drain/source structures 101 and 131 are isolated through the isolation structure 120, and the two drain/source structures 101 and 131 are not electrically contacted with each other. The two gate structures are isolated from each other through the isolation structure 120, and the two gate structures are not electrically contacted with each other.

As mentioned above, the P-type element 110 of the complementary field-effect transistor includes two nanosheets 102 and 104, and the N-type element 130 includes two nanosheets 132 and 134. The number of nanosheets in each of the P-type element 110 and the N-type element 130 is not restricted as long as the number is greater than or equal to 1.

Furthermore, the complementary field-effect transistor is not restricted to the transistor with one P-type element and one N-type element. For example, in some other embodiments, the complementary field-effect transistor includes two N-type elements in a stack arrangement, or the complementary field-effect transistor includes P-type elements in a stack arrangement.

In some embodiments of the complementary field-effect transistor, the drain/source structure 101 of the P-type element 110 in FIG. 1C is electrically connected with the drain/source structure 131 of the N-type element 130. That is, one drain/source terminal of the P-type element 110 is electrically connected with one drain/source terminal of the N-type element 130.

FIG. 1E is a schematic perspective view illustrating the structure of another complementary field-effect transistor. The drain/source structure 101 of the P-type element 110 and the drain/source structure 131 of the N-type element 130 are electrically connected with each other through a conducting wire 121. FIG. 1F is a schematic perspective view illustrating the structure of a further complementary field-effect transistor. After a portion of the isolation structure 120 is etched, a shared drain/source structure 126 is formed. That is, the drain/source structure 126 is shared by the P-type element 122 and the N-type element 124, indicating that the drain/source structure of the P-type element 122 is electrically connected with the drain/source structure of the N-type element.

In accordance with the present invention, a plurality of complementary field-effect transistors are collaboratively formed as a complementary field-effect transistor circuit (also referred to as a CFET circuit), and the CFET circuit includes at least one OTP memory cell. Furthermore, the OTP memory cell used in the present invention is an antifuse-type OTP memory cell. In the following embodiments, the complementary field-effect transistor in the CFET circuit includes a P-type element with two nanosheets and an N-type element with two nanosheets. The number of nanosheets in each of the P-type element and the N-type element is not restricted as long as the number is greater than or equal to 1.

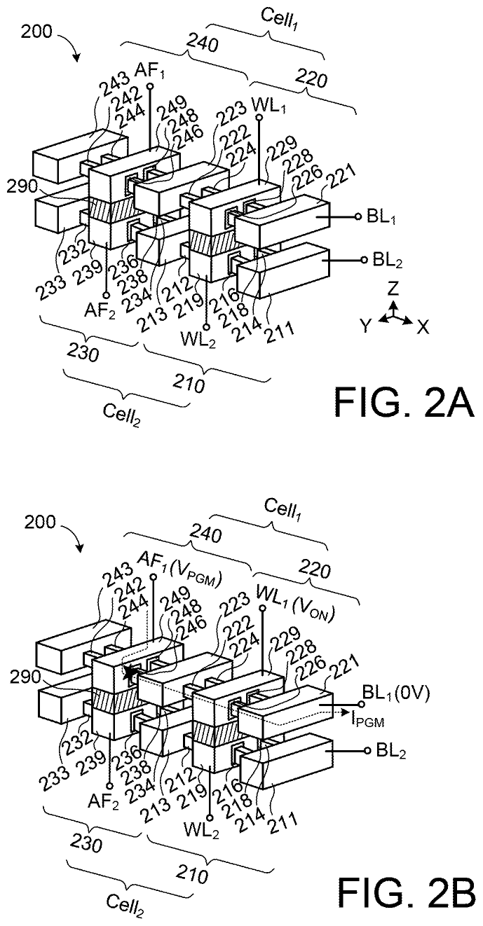

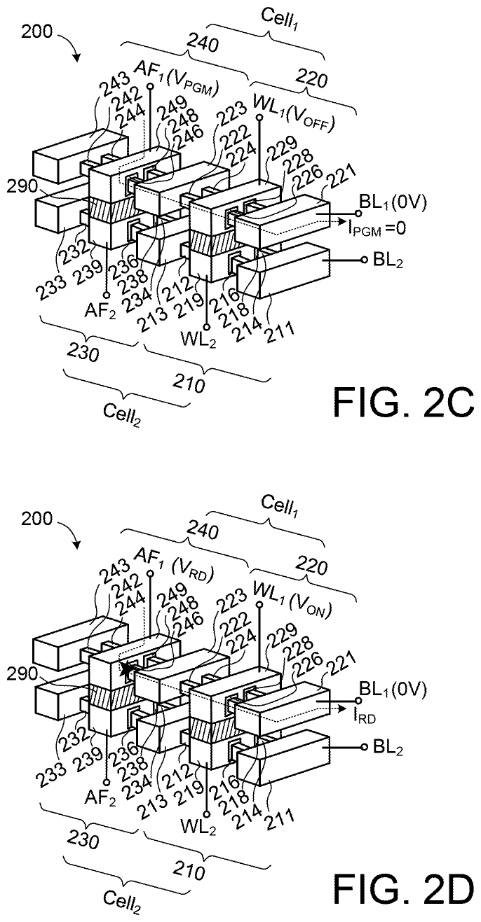

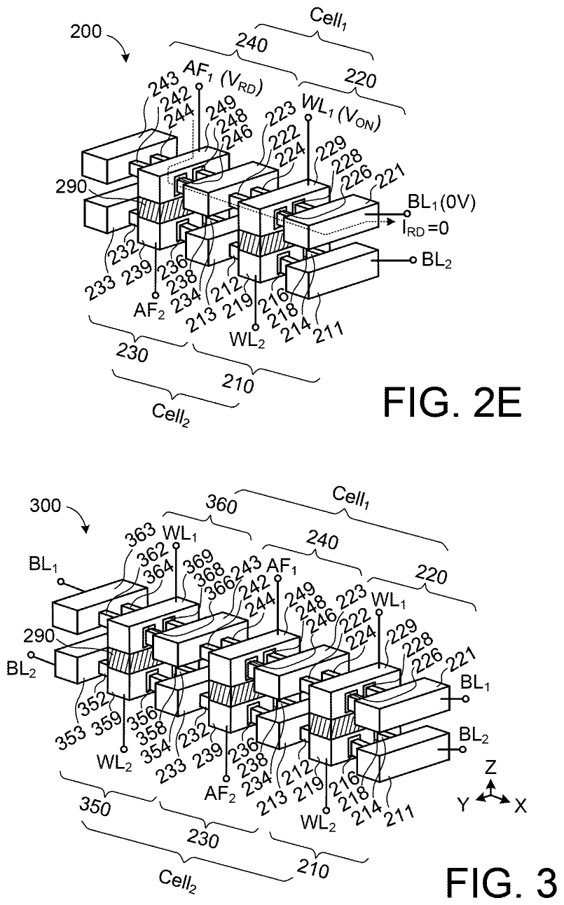

FIG. 2A schematically illustrates a CFET circuit according to a first embodiment of the present invention. In this embodiment, the CFET circuit 200 includes two complementary field-effect transistors. In order to facilitate understanding the structure of the CFET circuit 200, only the portion of the isolation structure 290 arranged between the two gate structures of each complementary field-effect transistor is shown and indicated by the oblique lines, and the other portion of the isolation structure 290 is not shown. Similar to FIG. 1C, the drain/source structures of each complementary field-effect transistor are also isolated by the isolation structure 290.

In the CFET circuit 200, the first complementary field-effect transistor includes a P-type element 210 and an N-type element 220, and the second complementary field-effect transistor includes a P-type element 230 and an N-type element 240. The P-type elements 210 and 230 are located under the isolation structure 290. The N-type elements 220 and 240 are located over the isolation structure 290. In addition, the structures of all complementary field-effect transistors in the CFET circuit 200 of the first embodiment are similar to the structure of the complementary field-effect transistor in FIG. 1C. For brevity, only the connection relationship between these complementary field-effect transistors will be described, and the structures of these complementary field-effect transistors will not be described in detail.

In the first embodiment, the CFET circuit 200 includes two OTP memory cells Cell₁ and Cell₂. The OTP memory cell Cell₁ includes two N-type elements 220 and 240. The OTP memory cell Cell₂ includes two P-type elements 210 and 230. Each of the OTP memory cells Cell₁ and Cell₂ can store a one-bit data. In other words, the CFET circuit 200 of FIG. 2A can store a two-bit data.

In the OTP memory cell Cell₁, the N-type element 220 serves as a selection element. The N-type element 220 includes two drain/source structures 221 and 223, a gate structure, and two nanosheets 222 and 224. The gate structure includes a gate layer 229 and two gate dielectric layers 226 and 228. The first terminals of the nanosheets 222 and 224 are electrically connected with the drain/source structure 221. The second terminals of the nanosheets 222 and 224 are electrically connected with the drain/source structure 223. Furthermore, the gate layer 229 is electrically connected with the word line WL₁, and the drain/source structure 221 is electrically connected with the bit line BL₁.

The N-type element 240 serves as an antifuse element. The N-type element 240 includes two drain/source structures 223 and 243, a gate structure, and two nanosheets 242 and 244. The gate structure includes a gate layer 249 and two gate dielectric layers 246 and 248. The first terminals of the nanosheets 242 and 244 are electrically connected with the drain/source structure 223. The second terminals of nanosheets 242 and 244 are electrically connected with the drain/source structure 243. The two N-type elements 220 and 240 share the drain/source structure 223. Furthermore, the gate layer 249 is electrically connected with an antifuse control line AF₁.

As mentioned above, in the OTP memory cell Cell₁, the first drain/source terminal of the N-type element 220 is electrically connected with the bit line BL₁, and the gate terminal of the N-type element 220 is electrically connected with the word line WL₁. The first drain/source terminal of the N-type element 240 is electrically coupled to the second drain/source terminal of the N-type element 220. The gate terminal of the N-type element 240 is electrically connected with the antifuse control line AF₁.

In the OTP memory cell Cell₂, the P-type element 210 serves as a select element. The P-type element 210 includes two drain/source structures 211 and 213, a gate structure, and two nanosheets 212 and 214. The gate structure includes a gate layer 219 and two gate dielectric layers 216 and 218. The first terminals of the nanosheets 212 and 214 are electrically connected with the drain/source structure 211. The second terminals of nanosheets 212 and 214 are electrically connected with the drain/source structure 213. Furthermore, the gate layer 219 is electrically connected with a word line WL₂, and the drain/source structure 211 is electrically connected with a bit line BL₂.

The P-type element 230 serves as an antifuse element. The P-type element 230 includes two drain/source structures 213 and 233, a gate structure, and two nanosheets 232 and 234. The gate structure includes a gate layer 239 and gate dielectric layers 236 and 238. The first terminals of the nanosheets 232 and 234 are electrically connected with the drain/source structure 213. The second terminals of nanosheets 232 and 234 are electrically connected with the drain/source structure 233. The two P-type elements 210 and 230 share the drain/source structure 213. Furthermore, the gate layer 239 is electrically connected with an antifuse control line AF₂.

When the gate oxide layer of the antifuse element in the OTP memory cell is unruptured, the internal resistance of the antifuse element is high, and the OTP memory cell is in an unruptured state. Conversely, when the gate oxide layer of the antifuse element is ruptured, the internal resistance of the antifuse element is very low, and the OTP memory cell is in a ruptured state. For example, the OTP memory cell in the ruptured state can be considered to store a logic value “1”, and the OTP memory cell in the unruptured state can be considered to store a logic value “0”.

FIGS. 2B and 2C illustrate associated bias voltages and operations of performing a program action on the CFET circuit according to the first embodiment of the present invention. FIGS. 2D and 2E illustrate associated bias voltages and operations of performing a read action on the CFET circuit according to the first embodiment of the present invention. Since the operating principles of the two OTP memory cells Cell₁ and Cell₂ are similar, the operations of performing the program action and the read action on the OTP memory cell Cell₁ of the CFET circuit 200 will be described as follows.

Please refer to FIG. 2B. When the program action is performed, the bit line BL₁ receives a ground voltage (0V), the word line WL₁ receives a turn-on voltage V_{ON}, and the antifuse control line AF₁ receives a program voltage V_{PGM}. For example, the program voltage V_{PGM} is in the range between 3V and 6V, and the turn-on voltage V_{ON} is in the range between 0.4V and 3V.

In the OTP memory cell Cell₁, the select element (i.e., the N-type element 220) is turned on, and the ground voltage (0V) received by the bit line BL₁ is transmitted to the nanosheets 242 and 244 of the antifuse element (i.e., N-type element 240). The two gate dielectric layers 246 and 248 of the antifuse element (i.e., the N-type element 240) are subjected to a voltage stress of the program voltage V_{PGM}. Consequently, one of the two gate dielectric layers 246 and 248 is ruptured, and a large program current I_{PGM} is generated. Under this circumstance, the OTP memory cell Cell₁ is programmed to a ruptured state. The program current I_{PGM} flows from the antifuse control line AF₁ to the bit line BL₁ through the antifuse element (i.e., the N-type element 240) and the select element (i.e., the N-type element 220).

Please refer to FIG. 2B. When the program action is performed, the gate dielectric layer 246 is ruptured, and thus the OTP memory cell Cell₁ is in the ruptured state. Similarly, in case that the gate dielectric layer 248 is ruptured during the program action, the OTP memory cell Cell₁ is in the ruptured state.

Please refer to FIG. 2C. When the program action is performed, the bit line BL₁ receives the ground voltage (0V), the word line WL₁ receives an off voltage V_{OFF}, and the antifuse control line AF₁ receives the program voltage V_{PGM}. For example, the off voltage V_{OFF} is 0V.

In the OTP memory cell Cell₁, the select element (i.e., the N-type element 220) is turned off. The ground voltage (0V) received by the bit line BL₁ cannot be transmitted to the nanosheets 242 and 244 of the antifuse element (i.e., the N-type element 240). The two gate dielectric layers 246 and 248 of the antifuse element (i.e., the N-type element 240) are not subjected to the voltage stress. Consequently, the two gate dielectric layers 246 and 248 are not ruptured, and the program current I_{PGM} is nearly zero. Under this circumstance, the OTP memory cell Cell₁ is remained in the unruptured state.

Of course, when the program action is performed, other bias voltages can be provided to maintain the OTP memory cell Cell₁ in the unruptured state. For example, when the program action is performed, the antifuse control line AF₁ and the bit line BL₁ receive a ground voltage (0V), and the word line WL₁ receives the turn-on voltage V_{ON}. Under this circumstance, the OTP memory cell Cell1 is also maintained in the unruptured state.

Please refer to FIGS. 2D and 2E. When the read action is performed, the bit line BL₁ receives the ground voltage (0V), the word line WL₁ receives the turn-on voltage V_{ON}, and antifuse control line AF₁ receives a read voltage V_{RD}. For example, the read voltage V_{RD} is in the range between 0.75V and 1.2V.

As shown in FIG. 2D, the select element (i.e., the N-type element 220) is turned on, and the antifuse element (i.e., the N-type element 240) is ruptured. Consequently, the OTP memory cell Cell₁ generates a large read current I_{RD}. The read current I_{RD} flows from the antifuse control line AF₁ to the bit line BL₁ through the antifuse element (i.e., N-type element 240) and the select element (i.e., N-type element 220).

As shown in FIG. 2E, the select element (i.e., the N-type element 220) is turned on, and the antifuse element (i.e., the N-type element 240) is in the unruptured state. Consequently, the OTP memory cell Cell₁ generates a small read current I_{RD} (nearly zero).

As mentioned above, after the program action is completed, the read action is performed. When the read operation is performed, the storage state of the OTP memory cell Cell₁ can be determined according to the magnitude of the read current I_{RD} on the bit line BL₁. For example, a current comparator is provided to receive the read current I_{RD} and a reference current Iref. If the read current I_{RD} is greater than the reference current I_{ref}, the OTP memory cell Cell₁ is determined to be in the ruptured state. Whereas, if the read current I_{RD} is less than the reference current Iref, the OTP memory cell Cell₁ is determined to be in the unruptured state.

In the CFET circuit 200 of the first embodiment, the N-type elements 220 and 240 are collaboratively formed as the OTP memory cell Cell₁, and the P-type elements 210 and 230 are collaboratively formed as the OTP memory cell Cell₂. It is noted that the types of the elements in the CFET circuit 200 are not restricted. In a variant example, the elements 210, 220, 230 and 240 in the CFET circuit 200 of the first embodiment are all N-type elements, and the two OTP memory cells Cell₁ and Cell₂ are both composed of the N-type elements. In another variant example, the elements 210, 220, 230 and 240 in the CFET circuit 200 of the first embodiment are all P-type elements, and the two OTP memory cells Cell₁ and Cell₂ are both composed of P-type elements.

FIG. 3 schematically illustrates a CFET circuit according to a second embodiment of the present invention. When compared with the first embodiment, the CFET circuit 300 of this embodiment further includes an additional complementary field-effect transistor. The additional complementary field-effect transistor includes a P-type element 350 and an N-type element 360. For brevity, only the connection relationship between the additional complementary field-effect transistor and associated components will be described.

In the second embodiment, the CFET circuit 300 includes two OTP memory cells Cell₁ and Cell₂. The OTP memory cell Cell₁ includes three N-type elements 220, 240 and 360. The OTP memory cell Cell₂ includes three P-type elements 210, 230 and 350. Each of the OTP memory cells Cell₁ and Cell₂ can store a one-bit data. In other words, the CFET circuit 300 of FIG. 3 can store a two-bit data.

In the OTP memory cell Cell₁, the N-type element 360 serves as a selection element. The N-type element 360 includes two drain/source structures 243 and 363, a gate structure, and two nanosheets 362 and 364. The gate structure includes a gate layer 369 and two gate dielectric layers 366 and 368. The first terminals of the nanosheets 362 and 364 are electrically connected with the drain/source structure 243. The second terminals of the nanosheets 362 and 364 are electrically connected with the drain/source structure 363. Furthermore, the gate layer 369 is electrically connected with the word line WL₁, and the drain/source structure 363 is electrically connected with the bit line BL₁. Furthermore, the two N-type elements 240 and 360 share the drain/source structure 243.

In the OTP memory cell Cell₂, the P-type element 350 serves as a select element. The P-type element 350 includes two drain/source structures 233 and 353, a gate structure, and two nanosheets 352 and 354. The gate structure includes a gate layer 359 and two gate dielectric layers 356 and 358. The first terminals of the nanosheets 352 and 354 are electrically connected with the drain/source structure 233. The second terminals of nanosheets 352 and 354 are electrically connected with the drain/source structure 353. Furthermore, the gate layer 359 is electrically connected with the word line WL₂, and the drain/source structure 353 is electrically connected with the bit line BL₂. Furthermore, the two P-type elements 230 and 350 share the drain/source structures 233.

As mentioned above, in the OTP memory cell Cell₁, the first drain/source terminal of the N-type element 360 is electrically coupled to the second drain/source terminal of the N-type element 240. The second drain/source terminal of the N-type element 360 is electrically connected with the bit line BL₁. The gate terminal of the N-type element 360 is electrically connected with the word line WL₁.

The bias voltages for performing the program action and the read action on the CFET circuit 300 of this embodiment are similar to those of the CFET circuit 200 of the first embodiment, and are not redundantly described herein.

In the CFET circuit 300 of the second embodiment, the N-type elements 220, 240 and 360 are collaboratively formed as the OTP memory cell Cell₁, and the P-type elements 210, 230 and 350 are collaboratively formed as the OTP memory cell Cell₂. It is noted that the types of the elements in the CFET circuit 300 are not restricted. In a variant example, the elements 210, 220, 230, 240, 350 and 360 in the CFET circuit 300 of the second embodiment are all N-type elements, and the two OTP memory cells Cell₁ and Cell₂ are both composed of the N-type elements. In another variant example, the elements 210, 220, 230, 240, 350 and 360 in the CFET circuit 300 of the second embodiment are all P-type elements, and the two OTP memory cells Cell₁ and Cell₂ are both composed of P-type elements.

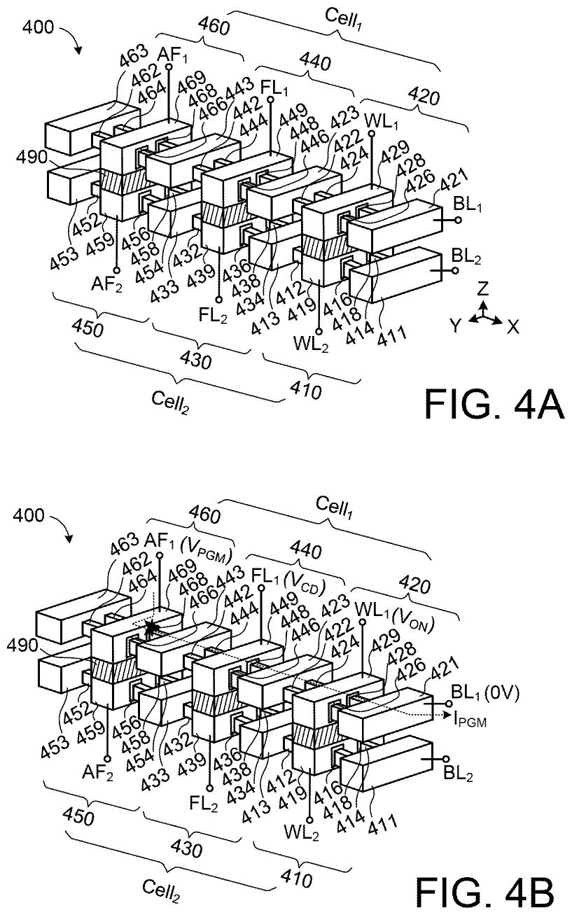

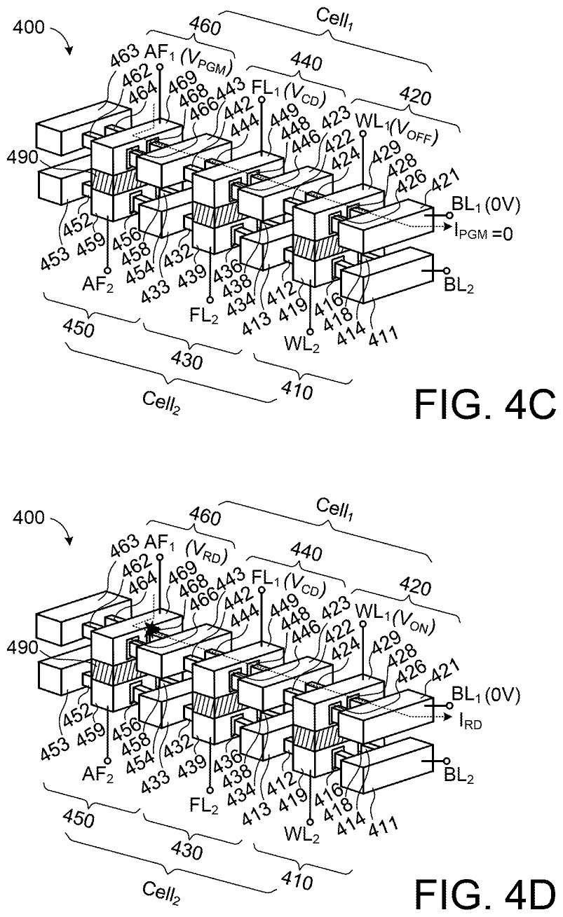

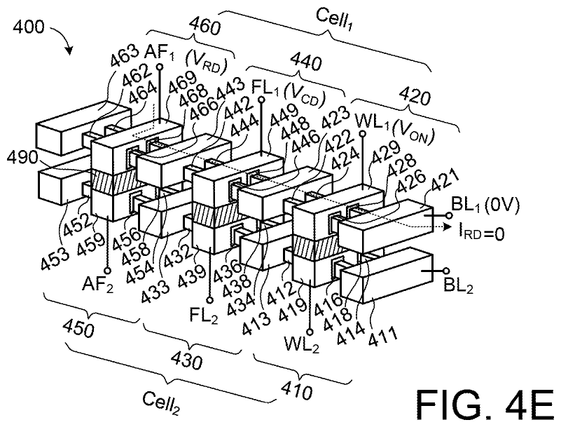

FIG. 4A schematically illustrates a CFET circuit according to a third embodiment of the present invention. In this embodiment, the CFET circuit 400 includes three complementary field-effect transistors. In order to facilitate understanding the structure of the CFET circuit 400, only the portion of the isolation structure 490 arranged between the two gate structures of each complementary field-effect transistor is shown and indicated by the oblique lines, and the other portion of the isolation structure 490 is not shown.

In the CFET circuit 400, the first complementary field-effect transistor includes a P-type element 410 and an N-type element 420, the second complementary field-effect transistor includes a P-type element 430 and an N-type element 440, and the third complementary field-effect transistor includes a P-type element 450 and an N-type element 460. The P-type elements 410, 430 and 450 are located under the isolation structure 490. The N-type elements 420, 440 and 460 are located over the isolation structure 490. In addition, the structures of all complementary field-effect transistors in the CFET circuit 400 of the third embodiment are similar to the structure of the complementary field-effect transistor in FIG. 1C.

In the third embodiment, the CFET circuit 400 includes two OTP memory cells Cell₁ and Cell₂. The OTP memory cell Cell₁ includes three N-type elements 420, 440 and 460. The OTP memory cell Cell₂ includes three P-type elements 410, 430 and 450. Each of the OTP memory cells Cell₁ and Cell₂ can store a one-bit data. In other words, the CFET circuit 400 of FIG. 4A can store a two-bit data.

In the OTP memory cell Cell₁, the N-type element 420 serves as a selection element. The N-type element 420 includes two drain/source structures 421 and 423, a gate structure, and two nanosheets 422 and 424. The gate structure includes a gate layer 429 and two gate dielectric layers 426 and 428. Furthermore, the gate layer 429 is electrically connected with the word line WL₁, and the drain/source structure 421 is electrically connected with the bit line BL₁.

The N-type element 440 serves as a following element. The N-type element 440 includes two drain/source structures 423 and 443, a gate structure, and two nanosheets 442 and 444. The gate structure includes a gate layer 449 and two gate dielectric layers 446 and 448. Furthermore, the gate layer 449 is electrically connected with a following control line FL₁.

The N-type element 460 serves as an antifuse element. The N-type element 460 includes two drain/source structures 443 and 463, a gate structure, and two nanosheets 462 and 464. The gate structure includes a gate layer 469 and two gate dielectric layers 466 and 468. Furthermore, the gate layer 469 is electrically connected with the antifuse control line AF₁.

As mentioned above, in the OTP memory cell Cell₁, the first drain/source terminal of the N-type element 420 is electrically connected with the bit line BL₁, and the gate terminal of the N-type element 420 is electrically connected with the word line WL₁. The first drain/source terminal of the N-type element 460 is electrically coupled to the second drain/source terminal of the N-type element 420. The gate terminal of the N-type element 460 is electrically connected with the antifuse control line AF₁. The first drain/source terminal of the N-type element 460 is electrically coupled to the second drain/source terminal of the N-type element 420 through the N-type element 440. The first drain/source terminal of the N-type element 440 is electrically connected with the second drain/source terminal of the N-type element 420. The second drain/source terminal of the N-type element 440 is electrically connected with the first drain/source terminal of the N-type element 460. Furthermore, the gate terminal of the N-type element 440 is electrically connected with a following control line FL₁.

In the OTP memory cell Cell₂, the P-type element 410 serves as a select element. The P-type element 410 includes two drain/source structures 411 and 413, a gate structure, and two nanosheets 412 and 414. The gate structure includes a gate layer 419 and two gate dielectric layers 416 and 418. Furthermore, the gate layer 419 is electrically connected with a word line WL₂, and the drain/source structure 411 is electrically connected with a bit line BL₂.

The P-type element 430 serves as a following element. The P-type element 430 includes two drain/source structures 413 and 433, a gate structure, and two nanosheets 432 and 434. The gate structure includes a gate layer 439 and two gate dielectric layers 436 and 438. Furthermore, the gate layer 439 is electrically connected with a following control line FL₂.

The P-type element 450 serves as an antifuse element. The P-type element 450 includes two drain/source structures 433 and 453, a gate structure, and two nanosheets 452 and 454. The gate structure includes a gate layer 459 and two gate dielectric layers 456 and 458. Furthermore, the gate layer 459 is electrically connected with an antifuse control line AF₂.

FIGS. 4B and 4C illustrate associated bias voltages and operations of performing a program action on the CFET circuit according to the third embodiment of the present invention. FIGS. 4D and 4E illustrate associated bias voltages and operations of performing a read action on the CFET circuit according to the third embodiment of the present invention. Since the operating principles of the two OTP memory cells Cell₁ and Cell₂ are similar, the operations of performing the program action and the read action on the OTP memory cell Cell₁ of the CFET circuit 400 will be described as follows.

Please refer to FIG. 4B. When the program action is performed, the bit line BL₁ receives a ground voltage (0V), the word line WL₁ receives a turn-on voltage V_{ON}, the following control line FL₁ receives a conducting voltage V_{CD}, and the antifuse control line AF₁ receives a program voltage V_{PGM}. For example, the program voltage V_{PGM} is in the range between 3V and 6V, the conducting voltage V_{CD} is in the range between 0.4V and 3V, and the turn-on voltage V_{ON} is in the range between 0.4V and 3V.

In OTP memory cell Cell₁, the select element (i.e., the N-type element 420) is turned on, the following element (i.e., the N-type element 440) is in a conducting state, and the ground voltage (0V) received by the bit line BL₁ is transmitted to the nanosheets 462 and 464 of the antifuse element (i.e., N-type element 460). The two gate dielectric layers 466 and 468 of the antifuse element (i.e., the N-type element 460) are subjected to a voltage stress of the program voltage V_{PGM}. Consequently, one of the two gate dielectric layers 466 and 468 is ruptured, and a large program current I_{PGM} is generated. Under this circumstance, the OTP memory cell Cell₁ is programmed to a ruptured state. The program current I_{PGM} flows from the antifuse control line AF₁ to the bit line BL₁ through the antifuse element (i.e., the N-type element 460), the following element (i.e., the N-type element 440) and the select element (i.e., the N-type element 420).

Please refer to FIG. 4B. When the program action is performed, the gate dielectric layer 468 is ruptured, and thus the OTP memory cell Cell₁ is in the ruptured state. Similarly, in case that the gate dielectric layer 466 is ruptured during the program action, the OTP memory cell Cell₂ is in the ruptured state.

Please refer to FIG. 4C. When the program action is performed, the bit line BL₁ receives the ground voltage (0V), the word line WL₁ receives an off voltage V_{OFF}, the following control line FL₁ receives the conducting voltage V_{CD}, and the antifuse control line AF₁ receives the program voltage V_{PGM}. For example, the off voltage V_{OFF} is 0V.

In the OTP memory cell Cell₁, the select element (i.e., the N-type element 420) is turned off. The ground voltage (0V) received by the bit line BL₁ cannot be transmitted to the nanosheets 462 and 464 of the antifuse element (i.e., the N-type element 460). The two gate dielectric layers 466 and 468 of the antifuse element (i.e., the N-type element 460) are not subjected to the voltage stress. Consequently, the two gate dielectric layers 466 and 468 are not ruptured, and the program current I_{PGM} is nearly zero. Under this circumstance, the OTP memory cell Cell₁ is remained in the unruptured state.

Of course, when the program action is performed, other bias voltages can be provided to maintain the OTP memory cell Cell₁ in the unruptured state. For example, when the program action is performed, the antifuse control line AF₁ and the bit line BL₁ receive a ground voltage (0V), the following control line FL₁ receives the conducting voltage V_{CD}, and the word line WL₁ receives the turn-on voltage V_{ON}. Under this circumstance, the OTP memory cell Cell1 is also maintained in the unruptured state.

Please refer to FIGS. 4D and 4E. When the read action is performed, the bit line BL₁ receives the ground voltage (0V), the word line WL₁ receives the turn-on voltage V_{ON}, the following control line FL₁ receives the conducting voltage V_{CD}, and antifuse control line AF₁ receives a read voltage V_{RD}. For example, the read voltage V_{RD} is in the range between 0.75V and 1.2V.

As shown in FIG. 4D, the select element (i.e., the N-type element 420) is turned on, the following element (i.e., the N-type element 440) is in the conducting state, and the antifuse element (i.e., the N-type element 460) is ruptured. Consequently, the OTP memory cell Cell₁ generates a large read current I_{RD}. The read current I_{RD} flows from the antifuse control line AF₁ to the bit line BL₁ through the antifuse element (i.e., N-type element 460), the following element (i.e., the N-type element 440) and the select element (i.e., N-type element 420).

As shown in FIG. 4E, the select element (i.e., the N-type element 420) is turned on, the following element (i.e., the N-type element 440) is in the conducting state, and the antifuse element (i.e., the N-type element 460) is in the unruptured state. Consequently, the OTP memory cell Cell₁ generates a small read current I_{RD} (nearly zero).

As mentioned above, after the program action is completed, the read action is performed. When the read operation is performed, the storage state of the OTP memory cell Cell₁ can be determined according to the magnitude of the read current I_{RD} on the bit line BL₁.

In the CFET circuit 400 of the third embodiment, the N-type elements 420, 440 and 460 are collaboratively formed as the OTP memory cell Cell₁, and the P-type elements 410, 430 and 450 are collaboratively formed as the OTP memory cell Cell₂. It is noted that the types of the elements in the CFET circuit 400 are not restricted. In a variant example, the elements 410, 420, 430, 440, 450 and 460 in the CFET circuit 400 of the third embodiment are all N-type elements, and the two OTP memory cells Cell₁ and Cell₂ are both composed of the N-type elements. In another variant example, the elements 410, 420, 430, 440, 450 and 460 in the CFET circuit 400 of the third embodiment are all P-type elements, and the two OTP memory cells Cell₁ and Cell₂ are both composed of P-type elements.

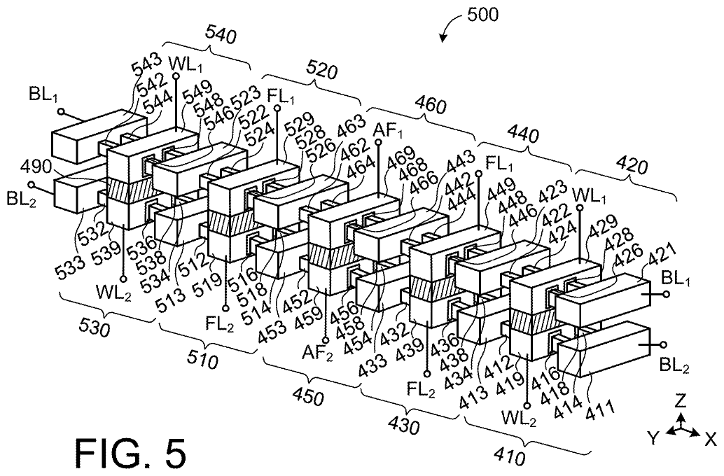

FIG. 5 schematically illustrates a CFET circuit according to a fourth embodiment of the present invention. When compared with the first embodiment, the CFET circuit 500 of this embodiment further includes two additional complementary field-effect transistors. The first additional complementary field-effect transistor includes a P-type element 510 and an N-type element 520. The second additional complementary field-effect transistor includes a P-type element 530 and an N-type element 540. For brevity, only the connection relationship between the additional complementary field-effect transistors and associated components will be described.

In the fourth embodiment, the CFET circuit 500 includes two OTP memory cells Cell₁ and Cell₂. The OTP memory cell Cell₁ includes five N-type elements 420, 440, 460, 520 and 540. The OTP memory cell Cell₂ includes five P-type elements 410, 430, 450, 510 and 530. Each of the OTP memory cells Cell₁ and Cell₂ can store a one-bit data. In other words, the CFET circuit 500 of FIG. 5 can store a two-bit data.

In the OTP memory cell Cell₁, the N-type element 520 serves as a following element. The N-type element 520 includes two drain/source structures 463 and 523, a gate structure, and two nanosheets 522 and 524. The gate structure includes a gate layer 529 and two gate dielectric layers 526 and 528. The first terminals of the nanosheets 522 and 524 are electrically connected with the drain/source structure 463. The second terminals of the nanosheets 522 and 524 are electrically connected with the drain/source structure 523. Furthermore, the gate layer 529 is electrically connected with a following control line FL₁. The two N-type elements 520 and 460 share the drain/source structure 463.

The N-type element 540 serves as a selection element. The N-type element 540 includes two drain/source structures 523 and 543, a gate structure, and two nanosheets 542 and 544. The gate structure includes a gate layer 549 and two gate dielectric layers 546 and 548. The first terminals of the nanosheets 542 and 544 are electrically connected with the drain/source structure 523. The second terminals of the nanosheets 542 and 544 are electrically connected with the drain/source structure 543. Furthermore, the gate layer 549 is electrically connected with the word line WL₁, and the drain/source structure 543 is electrically connected with the bit line BL₁. The two N-type elements 520 and 540 share the drain/source structure 523.

In the OTP memory cell Cell₂, the P-type element 510 serves as a following element. The P-type element 510 includes two drain/source structures 453 and 513, a gate structure, and two nanosheets 512 and 514. The gate structure includes a gate layer 519 and two gate dielectric layers 516 and 518. The first terminals of the nanosheets 512 and 514 are electrically connected with the drain/source structure 453. The second terminals of the nanosheets 512 and 514 are electrically connected with the drain/source structure 513. Furthermore, the gate layer 519 is electrically connected with a following control line FL₂. The two P-type elements 510 and 450 share the drain/source structure 453.

The P-type element 530 serves as a select element. The P-type element 530 includes two drain/source structures 513 and 533, a gate structure, and two nanosheets 532 and 534. The gate structure includes a gate layer 539 and two gate dielectric layers 536 and 538. The first terminals of the nanosheets 532 and 534 are electrically connected with the drain/source structure 513. The second terminals of the nanosheets 532 and 534 are electrically connected with the drain/source structure 533. Furthermore, the gate layer 539 is electrically connected with a word line WL₂, and the drain/source structure 533 is electrically connected with a bit line BL₂. The two P-type elements 510 and 530 share the drain/source structure 513.

As mentioned above, in the OTP memory cell Cell₁, the second drain/source terminal of the N-type element 540 is electrically connected with the bit line BL₁, and the gate terminal of the N-type element 540 is electrically connected with the word line WL₁. The second drain/source terminal of the N-type element 460 is electrically coupled to the first drain/source terminal of the N-type element 540. The second drain/source terminal of the N-type element 460 is electrically coupled to the first drain/source terminal of the N-type element 540 through the N-type element 520. The first drain/source terminal of the N-type element 520 is electrically connected with the second drain/source terminal of the N-type element 460. The second drain/source terminal of the N-type element 520 is electrically connected with the first drain/source terminal of the N-type element 540. The gate terminal of the N-type element 520 is electrically connected with the following control line FL₁.

The bias voltages for performing the program action and the read action on the CFET circuit 500 of this embodiment are similar to those of the CFET circuit 400 of the third embodiment, and are not redundantly described herein.

In the CFET circuit 500 of the fourth embodiment, the N-type elements 420, 440, 460, 520 and 540 are collaboratively formed as the OTP memory cell Cell₁, and the P-type elements 410, 430, 450, 510 and 530 are collaboratively formed as the OTP memory cell Cell₂. It is noted that the types of the elements in the CFET circuit 500 are not restricted. In a variant example, the elements 410, 420, 430, 440, 450, 460, 510, 520, 530 and 540 in the CFET circuit 500 of the fourth embodiment are all N-type elements, and the two OTP memory cells Cell₁ and Cell₂ are both composed of the N-type elements. In another variant example, the elements 410, 420, 430, 440, 450, 460, 510, 520, 530 and 540 in the CFET circuit 500 of the fourth embodiment are all P-type elements, and the two OTP memory cells Cell₁ and Cell₂ are both composed of P-type elements.

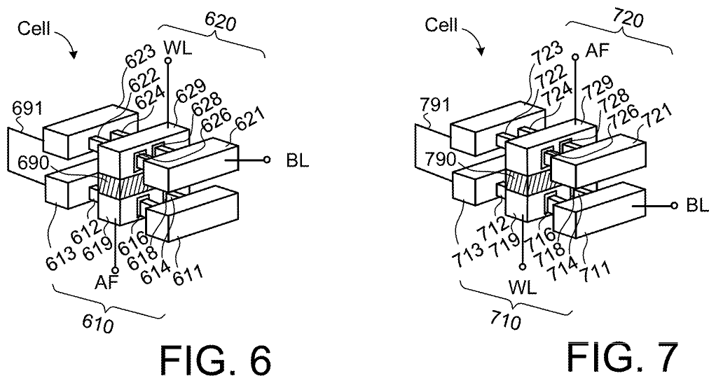

FIG. 6 schematically illustrates a CFET circuit according to a fifth embodiment of the present invention. In this embodiment, the CFET circuit includes a single complementary field-effect transistor. The complementary field-effect transistor includes a P-type element 610 and an N-type element 620. That is, the OTP memory cell Cell includes the P-type element 610 and the N-type element 620, and the OTP memory cells Cell can store a one-bit data.

In the OTP memory cell Cell, the N-type element 620 serves as a selection element. The N-type element 620 includes two drain/source structures 621 and 623, a gate structure, and two nanosheets 622 and 624. The gate structure includes a gate layer 629 and two gate dielectric layers 626 and 628. The first terminals of the nanosheets 622 and 624 are electrically connected with the drain/source structure 621. The second terminals of the nanosheets 622 and 624 are electrically connected with the drain/source structure 623. Furthermore, the gate layer 629 is electrically connected with a word line WL, and the drain/source structure 623 is electrically connected with a bit line BL.

The P-type element 610 serves as an antifuse element. The P-type element 610 includes two drain/source structures 611 and 613, a gate structure, and two nanosheets 612 and 614. The gate structure includes a gate layer 619 and two gate dielectric layers 616 and 618. The gate layer 619 is electrically connected with an antifuse control line AF. The first terminals of the nanosheets 612 and 614 are electrically connected with the drain/source structure 611. The second terminals of nanosheets 612 and 614 are electrically connected with the drain/source structure 613.

In the OTP memory cell Cell of this embodiment, the drain/source structure 613 of the P-type element 610 and the drain/source structure 623 of the N-type element 620 are connected with each other through a conducting line 691. Alternatively, the P-type element 610 and the N-type element 620 have a shared drain/source structure.

As mentioned above, in the OTP memory cell Cell, the first drain/source terminal of the N-type element 620 is electrically connected with the bit line BL, and the gate terminal of the N-type element 620 is electrically connected with the word line WL. The first drain/source terminal of the P-type element 610 is electrically connected with the second drain/source terminal of the N-type element 620. The gate terminal of the P-type element 610 is electrically connected with the antifuse control line AF.

The bias voltages for performing the program action and the read action on the CFET circuit of this embodiment are similar to those of the CFET circuit 200 of the first embodiment, and are not redundantly described herein.

In the CFET circuit of the fifth embodiment, the P-type element 610 and the N-type element 620 are collaboratively formed as the OTP memory cell Cell. It is noted that the types of the elements in the CFET circuit are not restricted. In a variant example, the elements 610 and 620 in the CFET circuit of the fifth embodiment are both N-type elements, and the OTP memory cell Cell is composed of the N-type elements. In another variant example, the elements 610 and 620 in the CFET circuit of the fifth embodiment are both P-type elements, and the OTP memory cell Cell is composed of P-type elements.

FIG. 7 schematically illustrates a CFET circuit according to a sixth embodiment of the present invention. In this embodiment, the CFET circuit includes a single complementary field-effect transistor. The complementary field-effect transistor includes a P-type element 710 and an N-type element 720. The P-type element 710 and the N-type element 720 are isolated from each other through an isolation structure 790. That is, the OTP memory cell Cell includes the P-type element 710 and the N-type element 720, and the OTP memory cell Cell can store a one-bit data.

In the OTP memory cell Cell, the P-type element 710 serves as a select element. The P-type element 710 includes two drain/source structures 711 and 713, a gate structure, and two nanosheets 712 and 714. The gate structure includes a gate layer 719 and two gate dielectric layers 716 and 718. The first terminals of the nanosheets 712 and 714 are electrically connected with the drain/source structure 711. The second terminals of nanosheets 712 and 714 are electrically connected with the drain/source structure 713. Furthermore, the gate layer 719 is electrically connected with a word line WL, and the drain/source structure 711 is electrically connected with a bit line BL.

The N-type element 720 serves as an antifuse element. The N-type element 720 includes two drain/source structures 721 and 723, a gate structure, and two nanosheets 722 and 724. The gate structure includes a gate layer 729 and two gate dielectric layers 726 and 728. The gate layer 729 is electrically connected with an antifuse control line AF. The first terminals of the nanosheets 722 and 724 are electrically connected with the drain/source structure 721. The second terminals of the nanosheets 722 and 724 are electrically connected with the drain/source structure 723.

In the OTP memory cell Cell of this embodiment, the drain/source structure 713 of the P-type element 710 and the drain/source structure 723 of the N-type element 720 are connected with each other through a conducting line 791. Alternatively, the P-type element 710 and the N-type element 720 have a shared drain/source structure.

As mentioned above, in the OTP memory cell Cell, the first drain/source terminal of the P-type element 710 is electrically connected with the bit line BL, and the gate terminal of the P-type element 710 is electrically connected with the word line WL. The first drain/source terminal of the N-type element 720 is electrically connected with the second drain/source terminal of the P-type element 710. The gate terminal of the N-type element 720 is electrically connected with the antifuse control line AF.

The bias voltages for performing the program action and the read action on the CFET circuit of this embodiment are similar to those of the CFET circuit 200 of the first embodiment, and are not redundantly described herein.

In the CFET circuit of the sixth embodiment, the N-type element 720 and the P-type element 710 are collaboratively formed as the OTP memory cell Cell. It is noted that the types of the elements in the CFET circuit are not restricted. In a variant example, the elements 710 and 720 in the CFET circuit of the sixth embodiment are both N-type elements, and the OTP memory cell Cell is composed of the N-type elements. In another variant example, the elements 710 and 720 in the CFET circuit of the sixth embodiment are both P-type elements, and the OTP memory cell Cell is composed of P-type elements.

As mentioned above, the present invention provides a CFET circuit and an OTP memory cell. When the program action is performed, proper bias voltages are provided to control the OTP memory cell to be selectively in the ruptured state or the unruptured state. When the read action is performed, proper voltages are provided to the OTP memory cell. Consequently, the OTP memory cell generates a read current I_{RD}. According to the magnitude of the read current I_{RD}, the storage state of the OTP memory cell is determined.

In the CFET circuits 200, 300, 400 and 500 of the above embodiments, the two OTP memory cells Cell₁ and Cell₂ are isolated from each other through the isolation structures 290 and 490. It is noted that numerous modifications may be made while retaining the teachings of the present invention. For example, when the program action is performed, only one OTP memory cell is programmed, but the other OTP memory cell is not programmed. For example, in the CFET circuit 200, only the OTP memory cell Cell₁ is programmed, but the OTP memory cell Cell₂ is not programmed. Under this circumstance, the OTP memory cell Cell₂ can be regarded as a fake OTP memory cell. In this way, the difficulty of cracking the data stored in non-volatile memory can be largely increased.

Similarly, the concepts of the fake OTP memory cell can be applied to the CFET circuits of the fifth embodiment and the sixth embodiment. For example, a plurality of memory cells Cell of the fifth embodiment are fabricated on two areas of the semiconductor substrate. When the program action is performed, only the OTP memory cells in the first area are programmed, but the OTP memory cells in the second area are not programmed. Under this circumstance, the OTP memory cells in the second area can be regarded as fake OTP memory cells. In this way, the difficulty of cracking the data stored in non-volatile memory can also be largely increased.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A complementary field-effect transistor circuit, comprising:
a first complementary field-effect transistor comprising a first element, a second element and an isolation structure; and
a second complementary field-effect transistor comprising a third element, a fourth element and the isolation structure,
wherein the second element and the fourth element are portions of a first one-time programmable memory cell, and the first element and the third element are portions of a second one-time programmable memory cell,
wherein the isolation structure is extended along an X-Y plane, the first one-time programmable memory cell is located beside a first side of the isolation structure in a Z direction, and the second one-time programmable memory cell is located beside a second side of the isolation structure in the Z direction,
wherein in the first one-time programmable memory cell, a first drain/source terminal of the second element is electrically connected with a first bit line, a gate terminal of the second element is electrically connected with a first word line, a first drain/source terminal of the fourth element is electrically coupled to a second drain/source terminal of the second element, and a gate terminal of the fourth element is electrically connected with a first antifuse control line.

2. The complementary field-effect transistor circuit as claimed in claim 1, wherein the second element is a first selection element, and the fourth element is a first antifuse element, wherein the first selection element comprises a first drain/source terminal a second drain/source terminal, a first nanosheet and a first gate structure, and the first antifuse element comprises the second drain/source terminal, a third drain/source terminal, a second nanosheet and a second gate structure, wherein the first gate structure comprises a first gate dielectric layer and a first gate layer, the first gate dielectric layer surrounds a center region of the first nanosheet, the first gate layer surrounds the first gate dielectric layer, the first drain/source terminal is electrically contacted with a first side region of the first nanosheet, the second drain/source terminal is electrically contacted with a second side region of the first nanosheet, the first drain/source terminal is electrically connected with the first bit line, and the first gate layer is electrically connected with the first word line, wherein the second gate structure comprises a second gate dielectric layer and a second gate layer, the second gate dielectric layer surrounds a center region of the second nanosheet, the second gate layer surrounds the second gate dielectric layer, the second drain/source terminal is electrically contacted with a first side region of the second nanosheet, the third drain/source terminal is electrically contacted with a second side region of the second nanosheet, and the second gate layer is electrically connected with the first antifuse control line.

3. The complementary field-effect transistor circuit as claimed in claim 2, wherein when a program action is performed, the first bit line receives a ground voltage, the first word line receives a turn-on voltage, and the first antifuse control line receives a program voltage, wherein the first selection element is turned on, and the second gate dielectric layer is subjected to a voltage stress equal to the program voltage, so that the second gate dielectric layer is ruptured and the first one-time programmable memory cell is in a ruptured state.

4. The complementary field-effect transistor circuit as claimed in claim 1, wherein in the second one-time programmable memory cell, a first drain/source terminal of the first element is electrically connected with a second bit line, a gate terminal of the first element is electrically connected with a second word line, a first drain/source terminal of the third element is electrically coupled to a second drain/source terminal of the first element, and a gate terminal of the third element is electrically connected with a second antifuse control line.

5. The complementary field-effect transistor circuit as claimed in claim 1, wherein the complementary field-effect transistor circuit further comprises a third complementary field-effect transistor, and the third complementary field-effect transistor comprises a fifth element, a sixth element and the isolation structure, wherein the first one-time programmable memory cell further comprises the sixth element, and the second one-time programmable memory cell further comprises the fifth element, wherein in the first one-time programmable memory cell, a first drain/source terminal of the sixth element is electrically connected with a second drain/source terminal of the fourth element, a second drain/source terminal of the sixth element is electrically connected with the first bit line, and a gate terminal of the sixth element is electrically connected with the first word line, wherein in the second one-time programmable memory cell, a first drain/source terminal of the fifth element is electrically connected with a second drain/source terminal of the third element, a second drain/source terminal of the fifth element is electrically connected with the second bit line, and a gate terminal of the fifth element is electrically connected with the second word line.

6. The complementary field-effect transistor circuit as claimed in claim 5, wherein the second element is a first selection element, the fourth element is a first antifuse element, and the sixth element is a second selection element, wherein the first selection element comprises a first drain/source terminal, a second drain/source terminal, a first nanosheet and a first gate structure, the first antifuse element comprises the second drain/source terminal, a third drain/source terminal, a second nanosheet and a second gate structure, and the second selection element comprises the third drain/source terminal, a fourth drain/source terminal, a third nanosheet and a third gate structure, wherein the first gate structure comprises a first gate dielectric layer and a first gate layer, the first gate dielectric layer surrounds a center region of the first nanosheet, the first gate layer surrounds the first gate dielectric layer, the first drain/source terminal is electrically contacted with a first side region of the first nanosheet, the second drain/source terminal is electrically contacted with a second side region of the first nanosheet, the first drain/source terminal is electrically connected with the first bit line, and the first gate layer is electrically connected with the first word line, wherein the second gate structure comprises a second gate dielectric layer and a second gate layer, the second gate dielectric layer surrounds a center region of the second nanosheet, the second gate layer surrounds the second gate dielectric layer, the second drain/source terminal is electrically contacted with a first side region of the second nanosheet, the third drain/source terminal is electrically contacted with a second side region of the second nanosheet, and the second gate layer is electrically connected with the first antifuse control line, wherein the third gate structure comprises a third gate dielectric layer and a third gate layer, the third gate dielectric layer surrounds a center region of the third nanosheet, the third gate layer surrounds the third gate dielectric layer, the third drain/source terminal is electrically contacted with a first side region of the third nanosheet, the fourth drain/source terminal is electrically contacted with a second side region of the third nanosheet, the third gate layer is electrically connected with the first word line, and the fourth drain/source terminal is electrically connected with the first bit line.

7. The complementary field-effect transistor circuit as claimed in claim 1, wherein the complementary field-effect transistor circuit further comprises a third complementary field-effect transistor, and the third complementary field-effect transistor comprises a fifth element, a sixth element and the isolation structure, wherein the first one-time programmable memory cell further comprises the sixth element, and the second one-time programmable memory cell further comprises the fifth element, wherein in the first one-time programmable memory cell, a first drain/source terminal of the fourth element is electrically coupled to the second drain/source terminal of the second element through the sixth element, and a gate terminal of the sixth element is electrically connected with a first following control line, wherein in the second one-time programmable memory cell, a first drain/source terminal of the third element is electrically coupled to the second drain/source terminal of the first element through the fifth element, and a gate terminal of the fifth element is electrically connected with a second following control line.

8. The complementary field-effect transistor circuit as claimed in claim 7, wherein the second element is a first selection element, the fourth element is a first antifuse element, and the sixth element is a first following element, wherein the first selection element comprises a first drain/source terminal, a second drain/source terminal, a first nanosheet and a first gate structure, the first following element comprises the second drain/source terminal, a third drain/source terminal, a second nanosheet and a second gate structure, the first antifuse element comprises the third drain/source terminal, a fourth drain/source terminal, a third nanosheet and a third gate structure, wherein the first gate structure comprises a first gate dielectric layer and a first gate layer, the first gate dielectric layer surrounds a center region of the first nanosheet, the first gate layer surrounds the first gate dielectric layer, the first drain/source terminal is electrically contacted with a first side region of the first nanosheet, the second drain/source terminal is electrically contacted with a second side region of the first nanosheet, the first drain/source terminal is electrically connected with the first bit line, and the first gate layer is electrically connected with the first word line, wherein the second gate structure comprises a second gate dielectric layer and a second gate layer, the second gate dielectric layer surrounds a center region of the second nanosheet, the second gate layer surrounds the second gate dielectric layer, the second drain/source terminal is electrically contacted with a first side region of the second nanosheet, the third drain/source terminal is electrically contacted with a second side region of the second nanosheet, and the second gate layer is electrically connected with the first following control line, wherein the third gate structure comprises a third gate dielectric layer and a third gate layer, the third gate dielectric layer surrounds a center region of the third nanosheet, the third gate layer surrounds the third gate dielectric layer, the third drain/source terminal is electrically contacted with a first side region of the third nanosheet, the fourth drain/source terminal is electrically contacted with a second side region of the third nanosheet, and the third gate layer is electrically connected with the first antifuse control line.

9. The complementary field-effect transistor circuit as claimed in claim 8, wherein when a program action is performed, the first bit line receives a ground voltage, the first word line receives a turn-on voltage, the first following control line receives a conducting voltage, and the first antifuse control line receives a program voltage, wherein the first selection element is turned on, the first following element is in a conducting state, and the third gate dielectric layer is subjected to a voltage stress equal to the program voltage, so that the third gate dielectric layer is ruptured and the first one-time programmable memory cell is in a ruptured state.

10. The complementary field-effect transistor circuit as claimed in claim 7, wherein the complementary field-effect transistor circuit further comprises a fourth complementary field-effect transistor and a fifth complementary field-effect transistor, wherein the fourth complementary field-effect transistor comprises a seventh element, an eighth element and the isolation structure, and the fifth complementary field-effect transistor comprises a ninth element, a tenth element and the isolation structure, wherein the first one-time programmable memory cell further comprises the eighth element and the tenth element, and the second one-time programmable memory cell further comprises the seventh element and the ninth element, wherein in the first one-time programmable memory cell, a first drain/source terminal of the eighth element is electrically connected with a second drain/source terminal of the fourth element, a gate terminal of the eighth element is electrically connected with the first following control line, a first drain/source terminal of the tenth element is electrically connected with a second drain/source terminal of the eighth element, a gate terminal of the tenth element is electrically connected with the first word line, and a second drain/source terminal of the tenth element is electrically connected with the first bit line, wherein in the second one-time programmable memory cell, a first drain/source terminal of the seventh element is electrically connected with a second drain/source terminal of the third element, a gate terminal of the seventh element is electrically connected with the second following control line, a first drain/source terminal of the ninth element is electrically connected with a second drain/source terminal of the seventh element, a gate terminal of the ninth element is electrically connected with the second word line, and a second drain/source terminal of the ninth element is electrically connected with the second bit line.

11. The complementary field-effect transistor circuit as claimed in claim 10, wherein the second element is a first selection element, the fourth element is a first antifuse element, the sixth element is a first following element, the eighth element is a second following element, and the tenth element is a second selection element, wherein the first selection element comprises a first drain/source terminal, a second drain/source terminal, a first nanosheet and a first gate structure, the first following element comprises the second drain/source terminal, a third drain/source terminal, a second nanosheet and a second gate structure, the first antifuse element comprises the third drain/source terminal, a fourth drain/source terminal, a third nanosheet and a third gate structure, the second following element comprises the fourth drain/source terminal, a fifth drain/source terminal, a fourth nanosheet and a fourth gate structure, and the second selection element comprises the fifth drain/source terminal, a sixth drain/source terminal, a fifth nanosheet and a fifth gate structure, wherein the first gate structure comprises a first gate dielectric layer and a first gate layer, the first gate dielectric layer surrounds a center region of the first nanosheet, the first gate layer surrounds the first gate dielectric layer, the first drain/source terminal is electrically contacted with a first side region of the first nanosheet, the second drain/source terminal is electrically contacted with a second side region of the first nanosheet, the first drain/source terminal is electrically connected with the first bit line, and the first gate layer is electrically connected with the first word line, wherein the second gate structure comprises a second gate dielectric layer and a second gate layer, the second gate dielectric layer surrounds a center region of the second nanosheet, the second gate layer surrounds the second gate dielectric layer, the second drain/source terminal is electrically contacted with a first side region of the second nanosheet, the third drain/source terminal is electrically contacted with a second side region of the second nanosheet, and the second gate layer is electrically connected with the first following control line, wherein the third gate structure comprises a third gate dielectric layer and a third gate layer, the third gate dielectric layer surrounds a center region of the third nanosheet, the third gate layer surrounds the third gate dielectric layer, the third drain/source terminal is electrically contacted with a first side region of the third nanosheet, the fourth drain/source terminal is electrically contacted with a second side region of the third nanosheet, and the third gate layer is electrically connected with the first antifuse control line, wherein the fourth gate structure includes a fourth gate dielectric layer and a fourth gate layer, the fourth gate dielectric layer surrounds a center region of the fourth nanosheet, the fourth gate layer surrounds the fourth gate dielectric layer, the fourth drain/source terminal is electrically contacted with a first side region of the fourth nanosheet, the fifth drain/source terminal is electrically contacted with a second side region of the fourth nanosheet, and the fourth gate layer is electrically connected with the first following control line, wherein the fifth gate structure includes a fifth gate dielectric layer and a fifth gate layer, the fifth gate dielectric layer surrounds a center region of the fifth nanosheet, the fifth gate layer surrounds the fifth gate dielectric layer, the fifth drain/source terminal is electrically contacted with a first side region of the fifth nanosheet, the sixth drain/source terminal is electrically contacted with a second side region of the fifth nanosheet, the sixth drain/source terminal is electrically connected with the first bit line, and the fifth gate layer is electrically connected with the first word line.

12. A complementary field-effect transistor circuit, comprising:
a first complementary field-effect transistor comprising a first element, a second element and an isolation structure,
wherein the first element and the second element are portions of a one-time programmable memory cell,
wherein the isolation structure is extended along an X-Y plane, the first element is located beside a first side of the isolation structure in a Z direction, and the second element is located beside a second side of the isolation structure in the Z direction,
wherein in the complementary field-effect transistor, a first drain/source terminal of the second element is electrically connected with a first bit line, a gate terminal of the second element is electrically connected with a first word line, a first drain/source terminal of the first element is electrically connected with a second drain/source terminal of the second element, and a gate terminal of the first element is electrically connected with an antifuse control line.

13. The complementary field-effect transistor circuit as claimed in claim 12, wherein the second element is a selection element, and the first element is an antifuse element, wherein the selection element comprises a first drain/source terminal, a second drain/source terminal, a first nanosheet and a first gate structure, and the antifuse element comprises a third drain/source terminal, a fourth drain/source terminal, a second nanosheet and a second gate structure, wherein the first gate structure comprises a first gate dielectric layer and a first gate layer, the first gate dielectric layer surrounds a center region of the first nanosheet, the first gate layer surrounds the first gate dielectric layer, the first drain/source terminal is electrically contacted with a first side region of the first nanosheet, the second drain/source terminal is electrically contacted with a second side region of the first nanosheet, the first drain/source terminal is electrically connected with the bit line, and the first gate layer is electrically connected with the word line, wherein the second gate structure comprises a second gate dielectric layer and a second gate layer, the second gate dielectric layer surrounds a center region of the second nanosheet, the second gate layer surrounds the second gate dielectric layer, the third drain/source terminal is electrically contacted with a first side region of the second nanosheet, the fourth drain/source terminal is electrically contacted with a second side region of the second nanosheet, the second gate layer is electrically connected with the antifuse control line, and the second drain/source terminal is electrically connected with the third drain/source terminal.

14. The complementary field-effect transistor circuit as claimed in claim 13, wherein when a program action is performed, the bit line receives a ground voltage, the word line receives a turn-on voltage, and the antifuse control line receives a program voltage, wherein the selection element is turned on, and the second gate dielectric layer is subjected to a voltage stress equal to the program voltage, so that the second gate dielectric layer is ruptured and the one-time programmable memory cell is in a ruptured state.
